(19) United States
(12) Patent Application Publication
(10) Pub. No.: US 2007/0047289 A1
(43) Pub. Date: Mar. 1, 2007

(54) SEMICONDUCTOR INTEGRATED CIRCUIT DEVICE

(75) Inventor: Isao Sasazaki, Kawasaki (JP)

Correspondence Address: ARENT FOX PLLC, 1050 CONNECTICUT AVENUE, N.W., SUITE 400, WASHINGTON, DC, 20036, US

(73) Assignee: FUJITSU LIMITED

(21) Appl. No.: 11/293,180

(22) Filed: Dec. 5, 2005

(30) Foreign Application Priority Data
Aug. 24, 2005 (JP) 2005-242925

(51) Int. Cl. G11C 11/22

(52) U.S. Cl. 365/145

(57) ABSTRACT

A semiconductor integrated circuit device capable of lengthening a life of a FeRAM. A RAM stores the same data as those of the FeRAM in the same address as that of the FeRAM. An FF (flip-flop) section stores validity of the data at each address on the RAM. When data at a specified address are valid with reference to the FF section at the time of data reading, a data access controller allows data reading from the RAM in place of the FeRAM.

### CROSS-REFERENCE TO RELATED APPLICATIONS

This application is based upon and claims the benefits of priority from the prior Japanese Patent Application No. 2005-242925, filed on Aug. 24, 2005, the entire contents of which are incorporated herein by reference.

### BACKGROUND OF THE INVENTION

1. Field of the Invention

The present invention relates to a semiconductor integrated circuit device, and more particularly to a semiconductor integrated circuit device having a FeRAM (Ferroelectric Random Access Memory).

2. Description of the Related Art

A FeRAM as a nonvolatile writable memory can realize low power consumption and high-speed writing and therefore, is expected to be applied to various fields.

In comparison with a flash memory, the FeRAM has the following characteristics:

No high voltage is required at the time of writing (for example, writing at a voltage of about 5 V is possible in contrast with a voltage of about 12 V for the flash memory);

Since no delete operation is required, data can be quickly updated; and

The number of times of writing is as many as about 10⁸ times or more in contrast with about 10⁵ times for the flash memory.

As application examples of the FeRAM, Japanese Unexamined Patent Publication No. 06-44064 (paragraph numbers [0009] to [0028], and FIG. 1) discloses a system where a FeRAM is used as a recording medium for storing firmware and in updating the firmware, an updated program is written in the FeRAM from an SRAM (Static RAM) in which the updated program is temporarily stored.

Further, Japanese Unexamined Patent Publication No. 2000-132461 (paragraph numbers [0011] to [0012], and FIG. 1) discloses a system where firmware is copied to a high-speed readable RAM from a FeRAM, and updating of the firmware is executed by an MPU (Micro Processing Unit).

However, the FeRAM is a data destructive read system memory. Therefore, when reading data from the FeRAM, a rewriting operation is required. As a result, there is a problem that a life of the FeRAM shortens every time the data is read.

### SUMMARY OF THE INVENTION

In view of the foregoing, it is an object of the present invention to provide a semiconductor integrated circuit device capable of lengthening a FeRAM life.

To accomplish the above object, according to one aspect of the present invention, there is provided a semiconductor integrated circuit device having a FeRAM. The semiconductor integrated circuit device comprises: a volatile storage medium that stores the same data as those of the FeRAM in the same address as that of the FeRAM; a validity storage section that stores validity of data at each address of the volatile storage medium; and a data access controller that, when data at a specified address are valid with reference to the validity storage section at the time of data reading, allows data reading from the volatile storage medium in place of the FeRAM.

The above and other objects, features and advantages of the present invention will become apparent from the following description when taken in conjunction with the accompanying drawings which illustrate preferred embodiments of the present invention by way of example.

### BRIEF DESCRIPTION OF THE DRAWINGS

FIG. 1 is a circuit diagram of a semiconductor integrated circuit device according to a first embodiment.

FIG. 2 illustrates a read operation in a case where data at a specified address are invalid.

FIG. 3 illustrates a read operation in a case where data at a specified address are valid.

FIG. 4 illustrates an operation of a semiconductor integrated circuit device at the time of a write request.

FIG. 5 is a circuit diagram of a semiconductor integrated circuit device according to a second embodiment.

### DESCRIPTION OF THE PREFERRED EMBODIMENTS

Preferred embodiments of the present invention are described in detail below with reference to the accompanying drawings, wherein like reference numerals refer to like elements throughout.

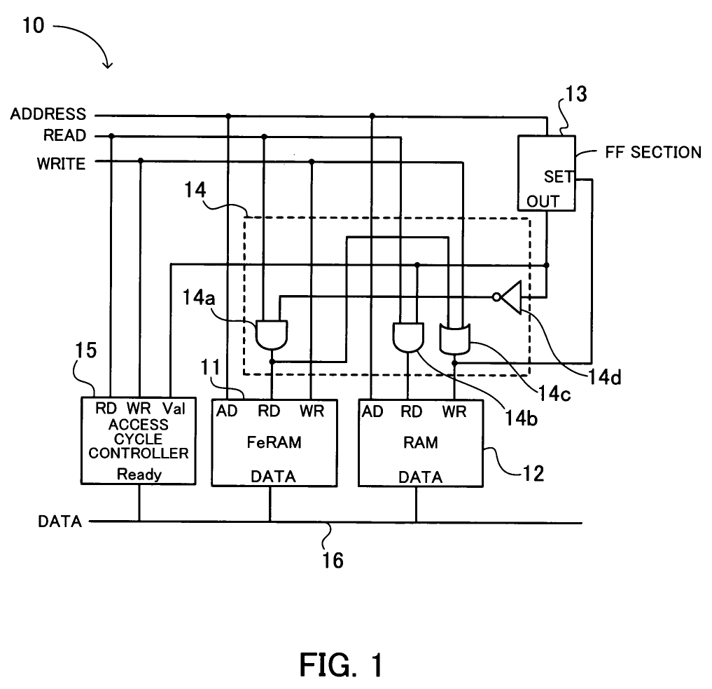

FIG. 1 is a circuit diagram of a semiconductor integrated circuit device according to a first embodiment.

A semiconductor integrated circuit device 10 according to the first embodiment comprises a FeRAM 11, a RAM 12, a flip-flop (FF) section 13, a data access controller 14 and an access cycle controller 15. Further, the FeRAM 11, the RAM 12 and the access cycle controller 15 are connected through a data line 16.

The FeRAM 11 is, for example, a nonvolatile storage medium that stores a program performed by a CPU (not shown) (Central Processing Unit). The FeRAM 11 has an AD terminal for inputting an address, a RD terminal for inputting a read signal, a WR terminal for inputting a write signal and a DATA terminal for inputting and outputting data.

The RAM 12 is a volatile storage medium. The RAM 12 is specified by the same address as that of the FeRAM 11 from the CPU (not shown). In other words, the RAM 12 shares the same address space with the FeRAM 11. Similarly to the FeRAM 11, also the RAM 12 has an AD terminal for inputting an address, a RD terminal for inputting a read signal, a WR terminal for inputting a write signal and a DATA terminal for inputting and outputting data.

The FF section 13 is composed of flip-flops in the number corresponding to the number of addresses on the FeRAM 11 or the RAM 12 (not shown in the figure). Each of the flip-flops stores a data valid flag showing validity of the data at each address on the RAM 12.

When data stored in one address on the FeRAM 11 are stored also in a relevant address on the RAM 12, the data are valid for the address. On the other hand, when the data are not stored in the relevant address on the RAM 12, the data are invalid for the address. Further, in an initial condition such as a power-on time, the data are invalid for all the addresses. The validity of the data can be changed by a signal inputted to a SET terminal (or a RESET terminal not shown in the figure) of each flip- flop. Hereinafter, description will be made on the assumption that when a value of the data valid flag is “0,” the data are invalid, whereas when a value of the data valid flag is “1,” the data are valid. A value of the data valid flag corresponding to a specified address is outputted from an OUT terminal.

The data access controller 14 is composed of AND circuits 14a and 14b, an OR circuit 14c and an inverter 14d. An input terminal of the inverter 14d is connected to the OUT terminal of the FF section 13. An output terminal of the inverter 14d is connected to one input terminal of the AND circuit 14a. Further, a read signal is inputted to the other input terminal of the AND circuit 14a. An output terminal of the AND circuit 14a is connected to the RD terminal of the FeRAM 11. One input terminal of the AND circuit 14b is connected to the OUT terminal of the FF section 13, and a read signal is inputted to the other input terminal of the AND circuit 14b. An output terminal of the AND circuit 14b is connected to the RD terminal of the RAM 12. A write signal is inputted to one input terminal of the OR circuit 14c, and the other input terminal of the OR circuit 14c is connected to the output terminal of the AND circuit 14a.

An output terminal of the OR circuit 14c is connected to the WR terminal of the RAM 12 and the SET terminal of each flip-flop of the FF section 13. The data access controller 14 as described above controls reading from or writing in the FeRAM 11 and the RAM 12 in response to a value of the data valid flag outputted from the FF section 13.

The access cycle controller 15 has a RD terminal for inputting a read signal, a WR terminal for inputting a write signal and a Val terminal for inputting an output signal from the FF section 13. In response to the signals inputted to the terminals, the controller 15 outputs from a Ready terminal a control signal for performing control of an access cycle in accordance with a difference between working speeds of the FeRAM 11 and the RAM 12.

Operations of the semiconductor integrated circuit device 10 according to the first embodiment will be described below.

First, an operation at the time of reading will be described.

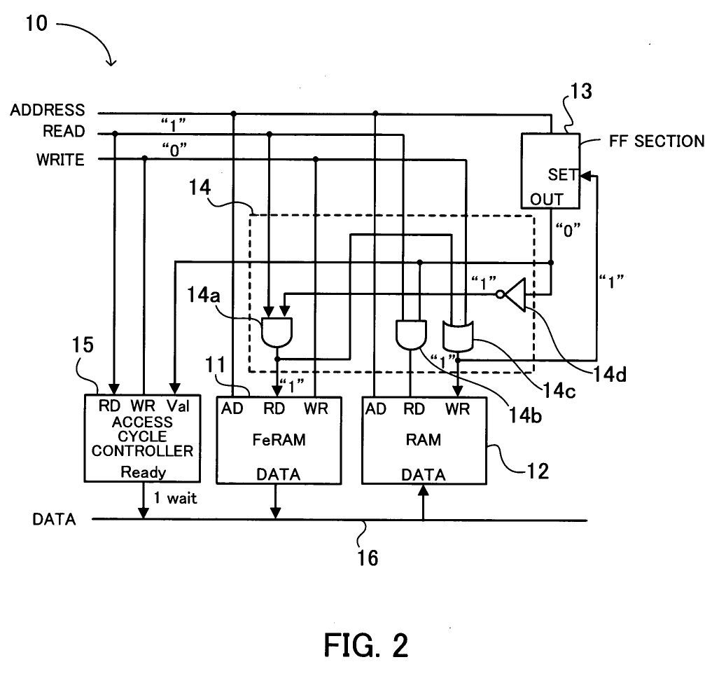

FIG. 2 illustrates a read operation in a case where data at a specified address are invalid.

For example, when a read request to the FeRAM 11 is performed by a CPU (not shown) (on this occasion, for example, a read signal is set to “1”), a value of the data valid flag of a flip-flop in the FF section 13 corresponding to a specified address is outputted in the FF section 13. When an output from the FF section 13 is “0” (invalid), an output of the inverter 14d is set to “1” in the data access controller 14. Further, also an output of the AND circuit 14a is set to “1” and is inputted to the RD terminal of the FeRAM 11. As a result, data reading from an address inputted to the AD terminal of the FeRAM 11 is performed.

On the other hand, since an output of the AND circuit 14b in the data access controller 14 is set to “0,” a read operation from the RAM 12 is not performed. However, since both of a write signal “0” and the output “1” of the AND circuit 14a are inputted to the OR circuit 14c in the data access controller 14, a write signal “1” is inputted to the WR terminal of the RAM 12 and a write operation to the RAM 12 is performed. Thus, the data read from the FeRAM 11 are written in the RAM 12 through the data line 16.

Further, in the access cycle controller 15, a signal “1” is inputted to the RD terminal and a signal “0” is inputted to the Val terminal. On this occasion, since both of the FeRAM 11 and the RAM 12 operate, the controller 15 controls an access cycle to be, for example, 1 wait (2 clock cycles) although a normal access cycle is 0 wait (1 clock cycle). Thus, the controller 15 sets an access cycle in consideration of a difference between working speeds of the FeRAM 11 and the RAM 12.

Further, the output “1” of the OR circuit 14c is inputted to the SET terminal of the flip-flop in the FF section 13 corresponding to the address specified this time, and as a result, a value of the data valid flag is changed into “1” (valid).

Next, a read operation in a case where data at a specified address are valid at the time of a read request will be described.

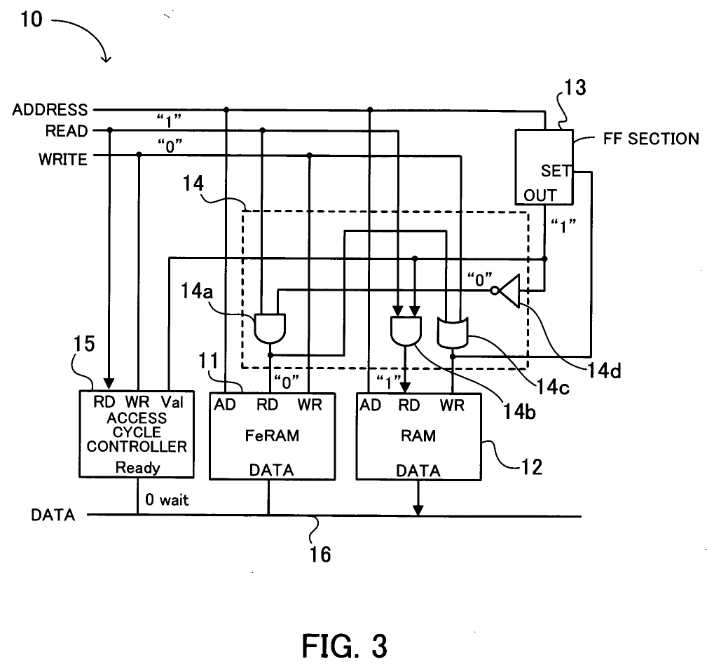

FIG. 3 illustrates a read operation in a case where data at a specified address are valid.

When a read request to the FeRAM 11 is performed by a CPU (not shown), a value of the data valid flag of a flip-flop in the FF section 13 corresponding to a specified address is outputted. When an output from the FF section 13 is “1” (valid), an output of the inverter 14d is set to “0” in the data access controller 14. On this occasion, a read signal “0” is inputted to the RD terminal of the FeRAM 11, and as a result, a read operation from the FeRAM 11 is not performed.

On the other hand, since an output of the AND circuit 14b in the data access controller 14 is set to “1,” data reading from an address inputted to the AD terminal of the RAM 12 is performed. Further, in the access cycle controller 15, a signal 11111 is inputted to the RD terminal and a signal “1” is inputted to the Val terminal. On this occasion, since only the RAM 12 operates, the controller 15 controls an access cycle to be 0 Wait.

Next, an operation at the time of a write request will be described.

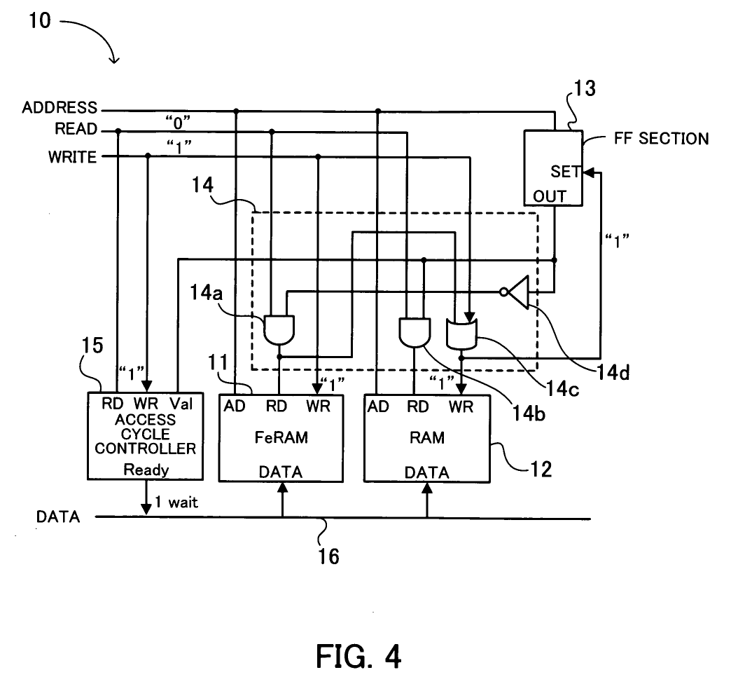

FIG. 4 illustrates an operation of the semiconductor integrated circuit device at the time of a write request.

When a write request to the FeRAM 11 is performed by a CPU (not shown), a write signal “1” is inputted to the WR terminal of the FeRAM 11. As a result, data are written in the specified address on the FeRAM 11 from the data line 16 through the DATA terminal. On the other hand, since the output of the OR circuit 14c in the data access controller 14 is “1” a write signal “1” is inputted also to the WR terminal of the RAM 12. As a result, the data are written in the same specified address on the RAM 12 as that on the FeRAM 11 through the DATA terminal. Further, in the access cycle controller 15, a write signal “1” is inputted to the WR terminal. On this occasion, since both of the FeRAM 11 and the RAM 12 operate as described above, the controller 15 controls an access cycle to be, for example, 1 wait. Further, the output “1” of the OR circuit 14c is inputted to the SET terminal of the flip-flop in the FF section 13 corresponding to an address specified this time, and as a result, a value of the data valid flag is changed into “1” (valid).

As described above, according to the semiconductor integrated circuit device 10 of the first embodiment, when data at the specified address are valid at the time of reading, that is, when data stored in one address on the FeRAM 11 are stored also in a relevant address on the RAM 12, the data can be read from the RAM 12 with no access to the FeRAM 11. Therefore, the number of times of reading from the FeRAM 11 can be reduced, and as a result, a life of the FeRAM 11 can be lengthened. Further, according to the semiconductor integrated circuit device 10 of the first embodiment, data copying from the FeRAM 11 to the RAM 12 is performed using hardware and therefore, can be performed at high speed.

Further, when performing data reading from the RAM 12, faster access is enabled as compared with data reading from the FeRAM 11.

Next, a semiconductor integrated circuit device according to a second embodiment will be described.

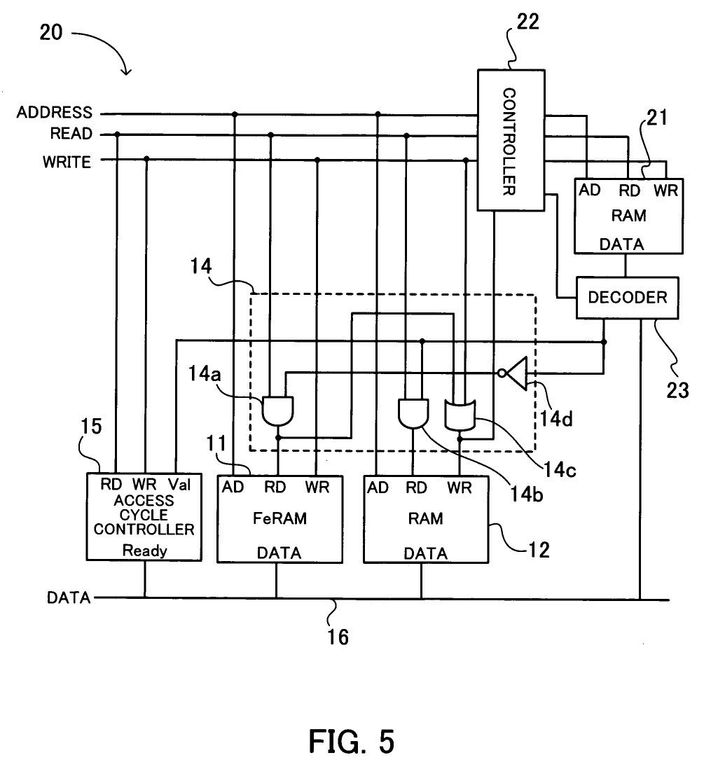

FIG. 5 is a circuit diagram of the semiconductor integrated circuit device according to the second embodiment.

In the diagram, the same elements as those in the semiconductor integrated circuit device 10 of the first embodiment are indicated by the same reference numerals as in the device 10 and the description is omitted.

A semiconductor integrated circuit device 20 according to the second embodiment has a RAM 21 as a validity storage section in place of the FF section 13 of the semiconductor integrated circuit device 10 according to the first embodiment. The device 20 further has a controller 22 and a decoder 23.

The RAM 21 has an AD terminal for inputting an address, a RD terminal for inputting a read signal, a WR terminal for inputting a write signal and a DATA terminal for inputting and outputting data. Further, through the DATA terminal, the RAM 21 performs reading or writing of data at an address specified by the controller 22, in response to a read signal or a write signal from the controller 22.

In response to a read request or write request from a CPU (not shown), the controller 22 controls the decoder 23 to control the reading from or writing in the RAM 21 of the validity indicating data corresponding to the RAM 12. Further, the controller 22 inputs the output of the OR circuit 14c in the above-described data access controller 14.

In accordance with the control of the controller 22, the decoder 23 makes a choice between inputting the data of the RAM 21 to the data access controller 14 and to the Val terminal of the access cycle controller 15, and outputting the data of the RAM 21 to the data line 16. Further, writing in the RAM 21 also is performed through the decoder 23 under the control of the controller 22.

Operations of the semiconductor integrated circuit device 20 according to the second embodiment will be simply described below. In an initial condition such as a power-on time, the controller 22 controls the decoder 23 to erase the whole validity indicating data which are stored in the RAM 21.

An operation at the time of reading will be described. When a read request is performed by a CPU (not shown), the controller 22 specifies an address on the RAM 21 storing data which indicate validity of data at a specified address (addresses of the FeRAM 11 and the RAM 12). At the same time, the controller 22 outputs a read signal. As a result, the RAM 21 outputs the validity indicating-data (“1” or “0”).

First, description will be made on a case where “0” (invalid) is outputted from the RAM 21. On this occasion, the controller 22 controls the decoder 23 to input “0” to the data access controller 14 and the access cycle controller 15. As a result, data are read from the FeRAM 11 as well as the data are written in the RAM 12, in the same manner as in the above-described operations of the semiconductor integrated circuit device 10 according to the first embodiment. However, the output of the OR circuit 14c in the data access controller 14 is inputted to the controller 22. When the output of the OR circuit 14c is “1,” the controller 22 controls the decoder 23 to rewrite from “0” to “1” the validity indicating data which are read this time from the RAM 21.

Next, description will be made on a case where “1” (valid) is outputted from the RAM 21. On this occasion, the controller 22 controls the decoder 23 to input “1” to the data access controller 14 and the access cycle controller 15. As a result, data at the specified address are read from the RAM 12 in place of the FeRAM 11, in the same manner as in the above-described operations of the semiconductor integrated circuit device 10 according to the first embodiment.

Also an operation at the time of writing is almost the same as that of the semiconductor integrated circuit device 10 according to the first embodiment described above. The output “1” of the OR circuit 14c in the data access controller 14 is inputted to the controller 22. The controller 22 controls the decoder 23 to rewrite from “0” to “1” the validity indicating data corresponding to the specified address.

As described above, even when storing the validity indicating-data using the RAM 21 in place of flip-flops, the semiconductor integrated circuit device 20 according to the second embodiment can provide the same effect as that in the semiconductor integrated circuit device 10 according to the first embodiment.

In the above, the present invention is described based on embodiments. However, the present invention is not limited to such embodiments. Various modifications are possible within the scope of the appended claims.

The semiconductor integrated circuit device according to the present invention comprises: a volatile storage medium that stores the same data as those of the FeRAM in the same address as that of the FeRAM; a validity storage section that stores validity of data at each address of the volatile storage medium; and a data access controller that, when data at a specified address are valid with reference to the validity storage section at the time of data reading, allows data reading from the volatile storage medium in place of the FeRAM. Therefore, the number of times of reading from the FeRAM can be reduced, and as a result, a life of the FeRAM can be lengthened.

The foregoing is considered as illustrative only of the principles of the present invention. Further, since numerous modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

What is claimed is:

1. A semiconductor integrated circuit device having a FeRAM, comprising:
a volatile storage medium that stores the same data as those of the FeRAM in the same address as that of the FeRAM;
a validity storage section that stores validity of data at each address of the volatile storage medium; and
a data access controller that, when data at a specified address are valid with reference to the validity storage section at the time of data reading, allows data reading from the volatile storage medium in place of the FeRAM.

2. The semiconductor integrated circuit device according to claim 1, wherein:
when the data at the specified address are invalid with reference to the validity storage section at the time of data reading, the data access controller allows data read from the FeRAM to be stored at the specified address of the volatile storage medium and allows the data at the specified address to be valid in the validity storage section.

3. The semiconductor integrated circuit device according to claim 1, wherein:
the data access controller allows data to be stored in specified addresses of both the FeRAM and the volatile storage medium at the time of data writing and allows the data at the specified addresses to be valid in the validity storage section.

4. The semiconductor integrated circuit device according to claim 1, wherein:
in an initial condition, the whole validity of data in the validity storage section is canceled out.

5. The semiconductor integrated circuit device according to claim 4, wherein:
the initial condition means a power-on time.

6. The semiconductor integrated circuit device according to claim 1, wherein:
the validity storage section is composed of a plurality of flip-flops.

7. The semiconductor integrated circuit device according to claim 1, wherein:
the validity storage section is composed of another volatile storage medium.
